(19) United States
(12) Patent Application Publication
(10) Pub. No.: US 2021/0287917 A1
(43) Pub. Date: Sep. 16, 2021

(54) CHIP MOLDING STRUCTURE, WAFER LEVEL CHIP SCALE PACKAGING STRUCTURE AND MANUFACTURING METHOD THEREOF

(71) Applicant: Changxin Memory Technologies, Inc., Hefei (CN)

(72) Inventors: Ling-Yi CHUANG, HEFEI (CN); Dingyou LIN, HEFEI (CN)

(21) Appl. No.: 17/331,133

(22) Filed: May 26, 2021

Related U.S. Application Data
(63) Continuation of application No. PCT/CN2019/121909, filed on Nov. 29, 2019.

(30) Foreign Application Priority Data
Nov. 30, 2018 (CN) 201811459386.7
Nov. 30, 2018 (CN) 201822028036.7

(51) Int. Cl. H01L 21/56; H01L 25/065; H01L 21/683; H01L 25/00; H01L 21/66; H01L 23/00

(52) U.S. Cl. CPC H01L 21/561; H01L 25/0657; H01L 21/6836; H01L 25/50; H01L 22/22; H01L 2924/37001; H01L 24/81; H01L 24/96; H01L 2224/16145; H01L 2225/06513; H01L 24/16

(57) ABSTRACT

A chip molding structure, a wafer level chip scale packaging structure and manufacturing methods thereof are disclosed, relating to the technical field of semiconductor production. The method of making a wafer level chip scale packaging structure includes: providing a wafer, comprising a plurality of bottom chips; bonding the wafer with a carrier; dicing the wafer to separate the plurality of bottom chips from a plurality of peripheral portions; removing the plurality of peripheral portions; and molding the plurality of bottom chips with a mold to form the molding structure. By dicing the wafer into independent bottom chips and peripheral portions, with the peripheral portions being removed before molding, the bottom chips may be prevented from being damaged during the molding. Compared with existing technologies, the packaging quality and production yield are improved.

### CROSS-REFERENCE TO RELATED APPLICATIONS

This application is a continuation application of International Patent Application No. PCT/CN2019/121909, filed on Nov. 29, 2019, which is based on and claims priority of the Chinese Patent Applications No. 201811459386.7 and No. 201822028036.7, both filed on Nov. 30, 2018. The above-referenced applications are incorporated herein by reference in their entirety.

### TECHNICAL FIELD

The present invention relates generally to the technical field of semiconductor production, and more specifically, but not by way of limitation, to a chip molding structure, a wafer level chip scale packaging structure and a manufacturing method thereof.

### BACKGROUND

Different from chip packaging method, wafer level chip scale packaging (WLCSP) first conducts packaging and test on wafer level, then the wafer may be diced into individual chips. Therefore, upon the completion of the packaging, the size of the package may be substantially equal to the original size of the bare chip.

In the molding process of wafer level packaging, a molding compound may initially be in a liquid state (or be heated to a liquid state), and the molding compound then may be cured through a cooling process. To ensure a predetermined molding density for the molding compound molded on the wafer surface, a certain injection molding pressure needs to be applied to the liquid molding compound within a mold.

In the molding process of existing wafer level packaging, the wafer may be clamped by annular upper and lower molds during the wafer level molding. Annular clamps of the molds may press the peripheral portions of the inner surface of the wafer to secure the wafer. Upon the completion of the molding, the annular clamps may be removed from the wafer.

While being pressed by the annular clamps, the peripheral portions of the wafer may be easily crushed or damaged, and the chips located at the peripheral portions of a neighboring wafer may also be affected, thus causing issues in molding quality and production yield.

In view of the above description, there is an urgent need for a solution that can overcome the issue that the peripheral portions of a wafer being susceptible to damage during molding and dicing processes of the wafer.

It is to be noted that the information disclosed in the above background is merely for strengthening the understanding on the background of the present invention and thus may include information not constituted into prior art known to a person of ordinary skill in the art.

### SUMMARY

In view of the deficiencies of existing technologies, the present invention provides a chip molding structure, a wafer level chip scale packaging structure and manufacturing methods thereof, that at least solve the issue that the peripheral portions of a wafer being susceptible to damage during molding and dicing processes of the wafer.

Other characteristics and advantages of the present invention may become apparent from the following detailed description or may be partially learnt from the practice of the present invention.

One aspect of the present invention is directed to a method of making a wafer level chip scale packaging structure. The method may include: providing a wafer, including a plurality of bottom chips; bonding the wafer with a carrier; dicing the wafer to separate the plurality of bottom chips from a plurality of peripheral portions; removing the plurality of peripheral portions; and molding the plurality of bottom chips with a mold to form the molding structure.

In some embodiments of the present invention, the method may further include: prior to the step of dicing the wafer, mounting a plurality of stacked chip sets on the plurality of bottom chips.

In some embodiments of the present invention, the method may further include: after the step of molding the plurality of bottom chips with a mold to form the molding structure, separating the carrier and the molding structure.

In some embodiments of the present invention, molding the plurality of bottom chips with a mold to form the molding structure may include: placing the plurality of bottom chips in a recess of the mold, with an inner diameter of the mole being greater than an outer diameter of the wafer; filling the recess of the mold with a molding compound; and curing the molding compound.

In some embodiments of the present invention, molding the plurality of bottom chips with a mold to form the molding structure may further include: covering side surfaces of the bottom chips mounted with the stacked chip sets with the molding compound, and covering an upper surface of the wafer with the molding compound.

In some embodiments of the present invention, the aforementioned method may further include: removing one or more bottom chips that are defective.

In some embodiments of the present invention, mounting a plurality of stacked chip sets on the plurality of bottom chips may include: mounting the plurality of stacked chip sets on the bottom chips tested to be normal.

In some embodiments of the present invention, separating the carrier and the molding structure may include: separating the carrier and the molding structure without removing the molding compound.

In some embodiments of the present invention, bonding the wafer with a carrier may include: bonding a surface of the wafer with the carrier through an adhesive tape.

Another aspect of the present invention is directed to a wafer level chip scale packaging structure. The structure may include: a plurality of bottom chips; a plurality of stacked chip sets, disposed on the plurality of bottom chips, with the plurality of bottom chips separated from each other by gaps; and a molding compound, covering side surfaces of the bottom chips.

In some embodiments of the present invention, the gaps may each have a width in a range of 50 μm to 200 μm.

In some embodiments of the present invention, the structure may further include: a carrier, bonded on bottom surfaces of the bottom chips.

In some embodiments of the present invention, the bottom chips may include a controller chip or a silicon interposer.

In some embodiments of the present invention, the structure may further include at least one of: a silicon through hole connecting a plurality of chips in one of the stacked chip sets; and, a mounting terminal disposed on the bottom surface of one of the bottom chips.

In some embodiments of the present invention, the bottom chips and the stacked chip sets may be connected via one of: a bump, a cylindrical bump having a soldering flux on a top end, or a solder ball.

In some embodiments of the present invention, the molding compound may cover a portion of a top surface of the bottom chips.

Another aspect of the present invention is directed to a chip molding structure. The chip molding structure may be manufactured with the manufacturing method of one of the aforementioned embodiments. The chip molding structure may include: a bottom chip; a stacked chip set, disposed on the bottom chip; and a molding compound, covering a side surface of the bottom chip.

In some embodiments of the present invention, the bottom chip and the stacked chip set may be connected via one of: a bump, a cylindrical bump having a soldering flux on a top end, or a solder ball.

In some embodiments of the present invention, the molding structure may further include a mounting terminal disposed on a bottom surface of the bottom chip.

In some embodiments of the present invention, the molding compound may cover a portion of a top surface of the bottom chip.

The technical solution provided by the embodiment of the present invention may include the following beneficial effects.

According to the technical solution provided by the exemplary embodiment of the present invention, by dicing a wafer into independent bottom chips and peripheral portions, with the peripheral portions being removed before molding, the bottom chips may be prevented from being damaged during the molding. Compared with existing technologies, the packaging quality and production yield of a WLCSP structure can be improved.

It is to be understood that both the foregoing general description and the following detailed description are exemplary and explanatory only and are not necessarily restrictive to the present invention.

### BRIEF DESCRIPTION OF THE DRAWINGS

The accompanying drawings, which are incorporated in and constitute a part of the specification, illustrate embodiments of the present invention and together with the specification, serve to explain the principles of the present invention. Apparently, the accompanying drawings in the following description are only some embodiments of the present invention, and a person of ordinary skill in the art can derive other drawings from the accompanying drawings without creative efforts.

FIG. 1 shows a schematic structural diagram of a wafer level chip scale packaging structure in the related art.

FIG. 2 shows a schematic structural diagram of a wafer level chip scale packaging structure in accordance with one embodiment of the present invention.

FIG. 3 shows a schematic structural diagram of a wafer level chip scale packaging structure in accordance with another embodiment of the present invention.

FIG. 4 shows a flowchart illustrating a manufacturing method of a wafer level chip scale packaging structure in accordance with one embodiment of the present invention.

FIG. 5 shows a flowchart illustrating a manufacturing method of a wafer level chip scale packaging structure in accordance with another embodiment of the present invention.

FIGS. 6, 7, 8, 9, and 10 are sectional systematic views of step S401 to step S405.

FIG. 11 shows a structural diagram of a chip molding structure in accordance with one embodiment of the present invention.

### DETAIL DESCRIPTION OF THE EMBODIMENTS

The exemplary embodiments will be described more completely with reference to the accompanying drawings. However, the exemplary embodiments can be implemented in various forms, and should not be understood as being limited to the embodiments described herein. Instead, these embodiments are provided to make the present invention thorough and complete and convey the concepts of the exemplary embodiments to the person skilled in the art fully. Identical numerals in the drawings represent an identical or similar structure and thus the detailed descriptions thereof are omitted.

Although relative terms are used in the specification, for example, “on” and “under” are used to describe a relative relationship of one numeral component to another component, these terms used in the specification are merely for the convenience, for instance, according to an exemplary direction in the drawings. It is to be understood that if a numeral module is reversed to turn upside down, a component described to be “on” will become a component to be “under”. Other relative terms such as “high”, “low”, “top”, “bottom”, “left” and “right” also have the similar meaning.

When a structure is “on” other structure, it may be indicated that the structure is integrally formed on the other structure, or indicated that the structure is “directly” disposed on the other structure, or indicated that the structure is “indirectly” disposed on the other structure via another structure.

Terms “a”, “an”, “one”, “the”, “said” and “at least one” are used to represent one or more elements/compositional portions/and the like. Terms “include”, “including”, “comprise”, “comprising”, “has” and “having” are used to represent a meaning of open inclusion and refer to that another elements/compositional portions/and the like may further be present besides the listed elements/compositional portions/and the like.

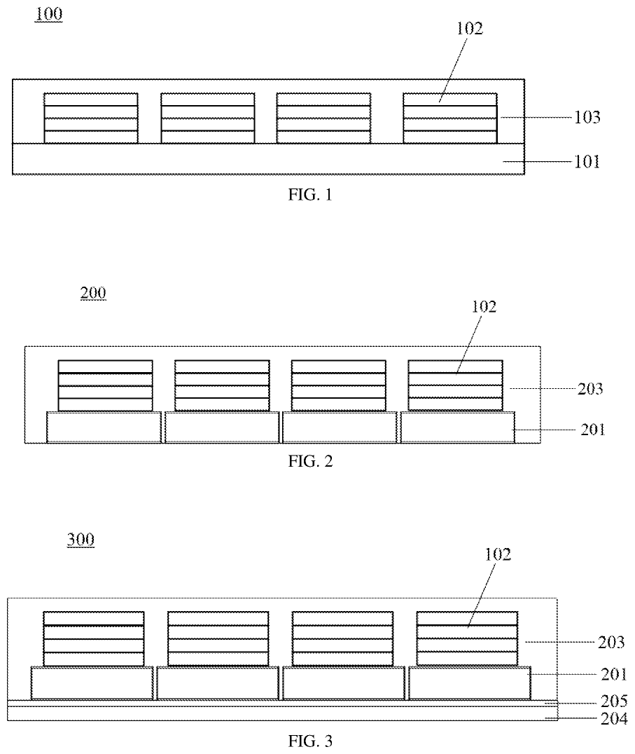

FIG. 1 shows a schematic structural diagram of a wafer level chip scale packaging structure in the related art. Referring to FIG. 1, in the wafer level chip scale packaging structure 100, a plurality of stacked chip sets 102 may be disposed on a wafer 101, and a molding compound 103 may cover an inner surface of the wafer 101. As the wafer has not been diced yet, the molding compound 103 may cover upper surfaces and side surfaces of the stacked chip sets 102, and cover portions of the inner surface of the wafer 101 not covered by the stacked chip sets 102.

As can be seen from the above description, when manufacturing the wafer level chip scale packaging structure, the wafer is first molded and then diced. Thus, when the wafer is placed between the upper and lower molds during the molding process, annular clamps of the upper and lower molds may press the peripheral portions of the inner surface (i.e., a surface of the wafer 101 facing upwards as shown in FIG. 1) of the wafer, thereby causing damage to the peripheral portions of the wafer and adversely affecting the packaging quality and production yield.

In the manufacturing process of the wafer level chip scale packaging structure provided by the present invention, instead of first molding the wafer followed by dicing the wafer, the wafer is diced first, and then, after the peripheral portions of the wafer are removed, the bottom chips are molded. Before the wafer is diced, a carrier may be bonded on an outer surface (i.e., a bottom surface) of the wafer. The carrier then may be removed after the inner surfaces (i.e., the top surfaces) of the bottom chips have been molded. Therefore, when the wafer is clamped by the upper and lower molds during the molding process, the annular clamp of the molds may press on the carrier, the upper mold no longer presses and contacts the peripheral portions of the wafer, the clamping stress of the mold is not directly transferred to the bottom chip. Thus, the peripheral portions of the wafer are not susceptible to damage. The exemplary embodiments of the present invention will be described below in detail with reference to the accompanying drawings.

FIG. 2 shows a schematic structural diagram of a wafer level chip scale packaging structure in accordance with one embodiment of the present invention. Referring to FIG. 2, the wafer level chip scale packaging structure 200 may include: a plurality of bottom chips 201; a plurality of stacked chip sets 102, disposed on the plurality of bottom chips. The multiple bottom chips may be separated from each other by gaps. The structure may further include a molding compound 203, covering inner surfaces of the bottom chips 201 and side surfaces of the bottom chips 201. As shown in FIG. 2, the plurality of bottom chips 201 may be separated from each other by gaps, and the gaps may be filled with the molding compound 203.

In this embodiment of the present invention, a wafer is diced before being molded, and non-chip peripheral blocks at the periphery of the wafer (i.e., peripheral portions of the wafer) may be removed, so that a molding compound may completely enclose bottom chips to prevent the bottom chips from being damaged by an external force. Thus, the packaging and manufacturing quality of the semiconductor device may be improved.

In this embodiment, the gaps may each have a width in a range of 50 μm to 200 μm. For example, each gap between the plurality of bottom chips may be: 80 μm, 110 μm, 140 μm or 170 μm.

The wafer may be diced by a diamond knife or a laser. Generally, a diamond knife may have a thickness in a range of 10 μm to 100 μm, so the width of each gap between the plurality of bottom chips is greater than the thickness of a diamond knife.

The plurality of stacked chip sets may include at least one semiconductor bare chip disposed on the bottom chips, and it may also include at least one integrated circuit (IC) disposed on the bottom chips. Each bottom chip may correspond, and be electrically connected, to one stacked chip set.

In some embodiments, the bottom chips may include a controller chip or a silicon interposer. The IC surfaces (i.e., the inner surfaces) of the bottom chips may face towards the stacked chip sets.

FIG. 3 shows a schematic structural diagram of a wafer level chip scale packaging structure in accordance with another embodiment of the present invention. The wafer level chip scale packaging structure 300, as shown in FIG. 3, and the wafer level chip scale packaging structure 200, as shown in FIG. 2, may each include a plurality of bottom chips 201, a plurality of stacked chip sets 102 and a molding compound 203. The difference between these two structures is that the wafer level chip scale packaging structure 300 may further include a carrier 204. The carrier 204 may be bonded with outer surfaces of the bottom chips 201 through an adhesive tape 205.

The bonding between the carrier 204 and the wafer may prevent the warpage of the wafer due to thin thickness of the wafer. The carrier may be a hard glass or a dicing tape.

A plurality of chips in one of the stacked chip sets 102 may be connected via a silicon through hole. The silicon through hole may also be referred to as a through silicon via (TSV).

The bottom chips and the stacked chip sets are connected via one of: a bump, a cylindrical bump having a soldering flux on a top end, or a solder ball.

A mounting terminal may be disposed on the outer surface of at least one of the bottom chips. The mounting terminal may also be referred to as a mounting combination terminal and may electrically connect the bottom chip to other devices. The mounting terminal may also be a welded ball or the bump and may also be the cylindrical bump with the soldering flux on the top end.

Additionally, it is to be noted that although the schematic diagrams shown in FIGS. 2 and 3 only include four bottom chips and four stacked chip sets, these schematic diagrams are merely exemplary systematic diagrams drawn to explaining the packaging structure. The wafer level chip scale packaging structure of the present invention may include multiple bottom chips and multiple stacked chip sets, with the exact numbers of the bottom chips and the stacked chip sets not being limited by the schematic diagrams of FIGS. 2 and 3.

In the wafer level chip scale packaging structure provided by the present invention, a wafer is first diced into individual bottom chips and the peripheral portions of the wafer. Then, after the peripheral portions are removed, the bottom chips are molded. Thus, the bottom chips may be prevented from being damaged during the molding process. Compared with existing technologies, the packaging quality and production yield of a WLCSP structure may be improved.

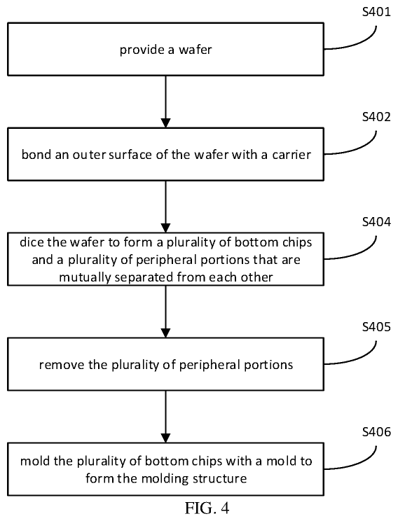

FIG. 4 shows a flowchart illustrating a manufacturing method of a wafer level chip scale packaging structure in accordance with one embodiment of the present invention.

As shown in FIG. 4, the manufacturing method may include the following steps.

In step S401, a wafer may be provided. The wafer may include a plurality of bottom chips.

In step S402, an outer surface of the wafer may be bonded with a carrier.

In step S404, the wafer may be diced to form the plurality of bottom chips and the peripheral portions of the wafer that are mutually separated from each other.

In step S405, the peripheral portions of the wafer may be removed.

In step S406, the plurality of bottom chips may be molded with a mold to form the molding structure.

In this embodiment of the present invention, a wafer is diced before being molded, and non-chip peripheral blocks at the periphery of the wafer (i.e., the peripheral portions of the wafer) may be removed, so that a molding compound may completely enclose bottom chips to prevent the bottom chips from being damaged by an external force. Thus, the packaging and manufacturing quality of the semiconductor device may be improved.

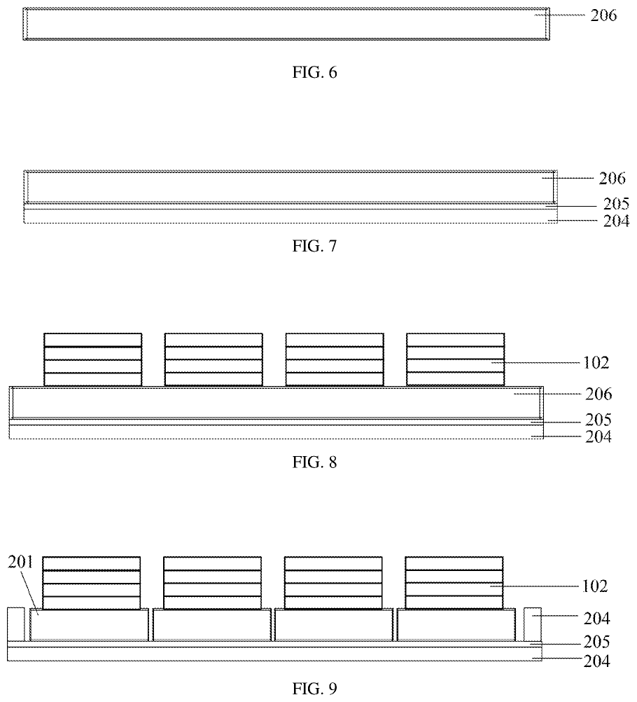

Upon the completion of step S401, a structure with a sectional systematic view as shown in FIG. 6 may be formed. The wafer 206 may include a plurality of bottom chips 201.

In step S402, the wafer may be bonded with the carrier through an adhesive tape. Upon the completion of step S402, a structure with a sectional systematic view as shown in FIG. 7 may be formed. As shown in FIG. 7, the outer surface of the wafer 206 may be bonded with the carrier 204 through the adhesive tape 205. The bonding between the carrier 204 and the wafer 206 may prevent the warpage of the wafer due to thin thickness of the wafer. In addition, the carrier 204 may further be bonded with an adhesive material via the wafer. The adhesive material may be heated to weaken its bonding force to the wafer to ease the removal of the carrier from to the wafer.

Step S404 may include a single ion dicing process on the wafer. Upon the completion of step S404, a structure with a sectional systematic view as shown in FIG. 9 may be formed.

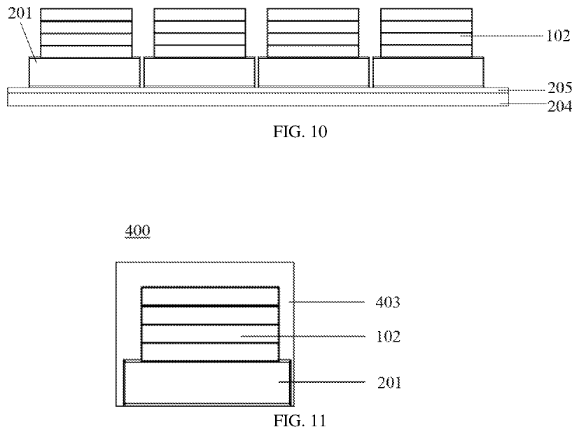

In step S405, when removing the peripheral portions of the wafer, one or more bottom chips that are tested to be defective may also be removed, thereby improving the production yield. Upon the completion of step S405, a structure with a sectional systematic view as shown in FIG. 10 may be formed.

In step S406, the plurality of bottom chips may be placed in a recess of the mold. An inner diameter of the mold may be greater than an outer diameter of the wafer. Then, the recess of the mold may be filled with a molding compound, which may be cured. Upon the completion of step S406, a structure with a sectional systematic view as shown in FIG. 3 may be formed.

When the molding compound is completely cured, a clamp of the mold may be separated from the carrier having the molding compound. At this time, the molding compound has completely molded and enclosed the stacked chip sets and the bottom chips. That is, the molding compound may enclose six surfaces of each of the stacked chip sets and the bottom chips.

Specifically, in the process of molding the plurality bottom chips with the mold, the molding compound may cover side surfaces of the plurality of bottom chips provided with the stacked chip sets and may cover an upper surface of the wafer.

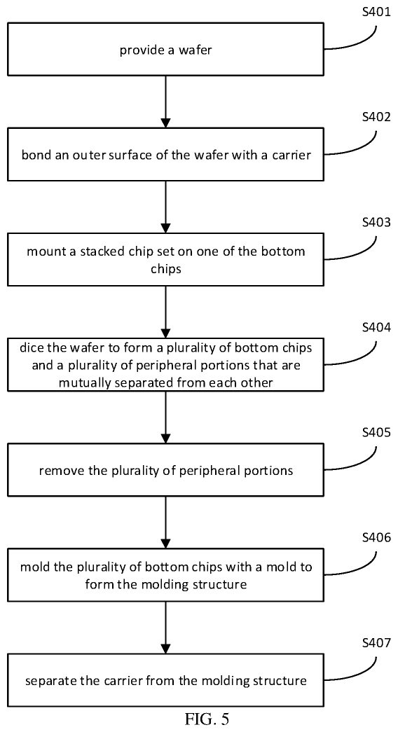

FIG. 5 shows a flowchart illustrating a manufacturing method of a wafer level chip scale packaging structure in accordance with another embodiment of the present invention. Referring to FIG. 5, in this method, steps S401, S402, S404, S405 and S406 may be the same as corresponding steps in the manufacturing method of FIG. 4. The difference between these two methods is that the manufacturing method of FIG. 5 may further include the following steps.

In step S403, a plurality of stacked chip sets may be mounted on the bottom chips.

In step S407, the carrier may be separated from the molding structure.

In step S403, the stacked chip sets may be disposed only on the bottom chips that have been tested to be normal. Upon the completion of step S403, a structure with a sectional systematic view as shown in FIG. 8 may be formed. Bottom chips that have been tested to be defective may be removed together with the peripheral portions of the wafer in step S405. If a stacked chip set is disposed on a bottom chip that has been tested to be defective, and a finished product is formed by going through a molding process, the finished product will be determined to be defective by a subsequent test process, thereby causing the scrap of an otherwise good-working stacked chip set. In step 403, by disposing the stacked chip sets only on the bottom chips that have been tested to be normal, unnecessary scrapping of the stacked chip sets may be prevented.

In some embodiments, step S403 may be performed after step S404.

In step S407, the molding structure may be separated from the carrier without removing the molding compound. Upon the completion of step S407, a structure with a sectional systematic view as shown in FIG. 2 may be formed.

Subsequently, the wafer level chip scale packaging structure may be subjected to the single ion dicing process to form individual chip molding structures. A diamond dicing process or a laser dicing process may be used during this process.

According to the manufacturing method of the wafer level chip scale packaging structure provided by this exemplary embodiment of the present invention, by dicing a wafer into independent bottom chips and the peripheral portions of the wafer, with the peripheral portions being removed before molding, the bottom chips may be prevented from being damaged during the molding. Compared with existing technologies, the packaging quality and production yield of a WLCSP structure may be improved.

The present invention further provides a chip molding structure. FIG. 11 shows a structural diagram of a chip molding structure in accordance with one embodiment of the present invention. The structure may be manufactured according to the manufacturing method of the wafer level chip scale packaging structure in any of the aforementioned embodiments. As shown in FIG. 11, the chip molding structure may include: a bottom chip 201; a stacked chip set 102, disposed on the bottom chip 201; and a molding compound 403, covering an inner surface of the bottom chip 201 and a side surface of the bottom chip 201.

The chip molding structure may be obtained by applying an single ion dicing process on the wafer level chip scale packaging structure 200 described in the aforementioned embodiment.

The bottom chip may include a controller chip or a silicon interposer.

A plurality chips in the stacked chip set 102 may be connected via a silicon through hole. The silicon through hole may also be referred to as a TSV. In the chip molding structure, the stacked chip set may include at least two ICs or at least two bare chips. The two ICs, or the two bare chips, may be connected via the silicon through hole.

The bottom chip and the stacked chip set may be connected via one of: a bump, a cylindrical bump having a soldering flux on a top end, or a solder ball.

A mounting terminal may be disposed on the outer surface of the bottom chip. The mounting terminal may also be referred to as a mounting combination terminal and may electrically connect the bottom chip to other devices. The mounting terminal may also be a welded ball or a bump and may also be a cylindrical bump with the soldering flux on the top end.

According to the chip molding structure provided by the present invention, by dicing a wafer into independent bottom chips and the peripheral portions of the wafer, with the peripheral portions being removed before molding, the bottom chips may be prevented from being damaged during the molding. Compared with existing technologies, the packaging quality and production yield of a WLCSP structure may be improved.

Other embodiments of the present invention will be apparent to the person skilled in the art from consideration of the specification and practice of the present invention disclosed here. The present invention is intended to cover any variations, uses, or adaptations of the present invention following the general principles thereof and including such departures from the present invention as come within known or customary practice in the art. It is intended that the specification and embodiment are considered as being exemplary only, with a true scope and spirit of the present invention indicated by the appended claims.

It is to be understood that the present invention is not limited to the accurate structures described above and shown in the accompanying drawings and may be subjected to various modifications and changes without departing from the scope of the present invention. The scope of the present invention is only limited by the appended claims.

1. A method of making a wafer level chip scale packaging (WLCSP) structure, comprising:
providing a wafer, comprising a plurality of bottom chips;
bonding the wafer with a carrier;
dicing the wafer to separate the plurality of bottom chips from a plurality of peripheral portions;
removing the plurality of peripheral portions; and
molding the plurality of bottom chips with a mold to form the molding structure.

2. The method of claim 1, further comprising: prior to the step of dicing the wafer,
mounting a plurality of stacked chip sets on the plurality of bottom chips.

3. The method of claim 2, further comprising: after the step of molding the plurality of bottom chips with a mold to form the molding structure,
separating the carrier and the molding structure.

4. The method of claim 3, wherein molding the plurality of bottom chips with a mold to form the molding structure comprises:
placing the plurality of bottom chips in a recess of the mold, wherein an inner diameter of the mold is greater than an outer diameter of the wafer;
filling the recess of the mold with a molding compound; and
curing the molding compound.

5. The method of claim 4, wherein molding the plurality of bottom chips with a mold to form the molding structure further comprises:
covering side surfaces of the bottom chips mounted with the stacked chip sets with the molding compound and covering an upper surface of the wafer with the molding compound.

6. The method of claim 5, further comprising:
removing one or more bottom chips that are defective.

7. The method of claim 6, wherein mounting a plurality of stacked chip sets on the plurality of bottom chips comprises:
mounting the plurality of stacked chip sets on the bottom chips tested to be normal.

8. The method of claim 7, wherein separating the carrier and the molding structure comprises:
separating, without removing the molding compound, the carrier and the molding structure.

9. The method of claim 8, wherein bonding the wafer with a carrier comprises:
bonding a surface of the wafer with the carrier with an adhesive tape.

10. A wafer level chip scale packaging (WLCSP) structure, comprising:
a plurality of bottom chips;
a plurality of stacked chip sets, disposed on the plurality of bottom chips, wherein the plurality of bottom chips is separated from each other by gaps; and
a molding compound, covering side surfaces of the bottom chips.

11. The structure of claim 10, wherein the gaps each have a width in a range of 50 μm to 200 μm.

12. The structure of claim 11, further comprising:
a carrier bonded on bottom surfaces of the bottom chips.

13. The structure of claim 12, wherein the bottom chips comprise a controller chip or a silicon interposer.

14. The structure of claim 13, further comprising at least one of:
a silicon through hole connecting a plurality of chips in one of the stacked chip sets; and
a mounting terminal disposed on the bottom surface of one of the bottom chips.

15. The structure of claim 14, wherein the bottom chips and the stacked chip sets are connected via one of: a bump, a cylindrical bump having a soldering flux on a top end, or a solder ball.

16. The structure of claim 10, wherein the molding compound covers a portion of a top surface of the bottom chips.

17. A chip molding structure, wherein the structure is manufactured with the manufacturing method of claim 1, and wherein the structure comprises:
a bottom chip;
a stacked chip set disposed on the bottom chip; and
a molding compound, covering a side surface of the bottom chip.

18. The structure of claim 17, wherein the bottom chip and the stacked chip set are connected via one of: a bump, a cylindrical bump having a soldering flux on a top end, or a solder ball.

19. The structure of claim 17, further comprising a mounting terminal disposed on a bottom surface of the bottom chip.

20. The structure of claim 17, wherein the molding compound covers a portion of a top surface of the bottom chip.
